(19) United States
(12) Patent Application Publication
(10) Pub. No.: US 2008/0119011 A1
(43) Pub. Date: May 22, 2008

(54) METHOD OF FILM COATING AND DEVICE MANUFACTURED THEREBY

(75) Inventors: JHIH-PING LU, Zhudong Town (TW); YUH-ZHENG LEE, Hsinchu City (TW); KUO-TONG LIN, Tucheng City (TW)

Correspondence Address: Akin Gump LLP - Silicon Valley, 3000 El Camino Real, Two Palo Alto Square, Suite 400, Palo Alto, CA, 94306, US

(73) Assignee: INDUSTRIAL TECHNOLOGY RESEARCH INSTITUTE, Hsinchu (TW)

(21) Appl. No.: 11/862,168

(22) Filed: Sep. 26, 2007

Related U.S. Application Data
(60) Provisional application No. 60/866,440, filed on Nov. 20, 2006.

(51) Int. Cl. H01L 51/40

(52) U.S. Cl. 438/99; 257/E51.024

(57) ABSTRACT

A method of forming a continuous layer of film, the method comprising providing a substrate having a surface, forming a first patterned layer of film on the surface, the first patterned layer of film including a plurality of first film units separated from each other, and forming a second patterned layer of film over the first patterned layer of film, the second patterned layer of film extending along the first patterned layer of film and including a plurality of second film units separated from each other, each of the plurality of second film units connecting at least two immediately adjacent first film units of the first patterned layer of film

### CROSS-REFERENCE TO RELATED APPLICATIONS

This application claims the benefit of U.S. Provisional Application No. 60/866,440, filed Nov. 20, 2006.

### BACKGROUND OF THE INVENTION

The present invention relates generally to film coating, and more particularly, to a method capable of coating a film on a surface layer and a device manufactured by the method.

With the increasing interest in compact, light-weight and low-profile electronic products, many products are manufactured with miniature feature sizes. For example, the progress in inorganic semiconductor manufacturing technologies satisfies the demands for the down-sized electronic products and components. However, the inorganic semiconductor manufacturing technologies generally include high-temperature steps and expensive processes. To address these issues, flexible substrates made of organic materials that support low-temperature and relatively cost-efficient fabrication have been developed. Flexible substrates may be manufactured by film coating processes, such as spin coating or inkjet printing. The inkjet printing process may be advantageous in its direct and large-area deposition ability at relatively low cost and may be used in various applications ranging from manufacturing passive components (such as resistors, inductors and capacitors), active components (such as thin film transistors and memory devices), and electronic products (such as displays, sensors and solar cells).

With all the advantages and competitiveness over inorganic semiconductor processes, organic processes generally do not provide a smooth and uniform layer of film coated on a surface, probably due to the differences in surface energy between the surface and a solution that subsequently forms the film. FIG. 1A is a schematic diagram illustrating a liquid film 12 insensitive to a substrate 10, and FIG. 1B is a schematic diagram illustrating a liquid film 13 sensitive to a substrate 11. Referring to FIG. 1A, which illustrates an example of a conventional inkjet printing system, ink droplets 14 are ejected from a nozzle of an inkjet head 16 toward a surface 10-1 of the substrate 10 as the inkjet head 16 traverses across the substrate 10. Since the film 12 is insensitive to the surface 10-1, that is, having a relatively high affinity with the surface 10-1, the film 12 spreads and wets the surface 10-1 and subsequently becomes a substantially smooth and uniform layer thereon. Referring to FIG. 1B, however, if the film 13 is sensitive to a surface 11-1 of the substrate 11, that is, having a relatively low affinity with the surface 11-1, the cohesion in the liquid film 13 is greater than the surface tension, undesirably resulting in a discontinuous film layer on the surface 11-1. Generally, a film is said to have a relatively high affinity with a substrate if the surface contact angle θ is greater than 45°, and have a relatively low affinity with a substrate if the surface contact angle θ is smaller than 45°. The surface contact angle refers to an angle at which a liquid or vapor interface meets a solid interface.

To address the issue with the organic processes, many methods have been proposed. An example of the conventional methods can be found in U.S. Pat. No. 6,145,979 to Caiger et al., entitled “Ink Jet Printer with Apparatus for Curing Ink and Method.” Caiger et al. discloses a process and apparatus for forming an image on a moving substrate, which involves inkjet printing a radiation-curable ink onto the substrate with a print head. This kind of method generally requires a heating source, which may be destructive to a sensitive film. Another example of the conventional methods can be found in U.S. Patent Application Ser. No. 20050123696 filed by Campbell et al., entitled “Plasma Treatment of Porous Inkjet Receivers.” Campbell et al. discloses an inkjet recording element comprising a porous ink-receiving layer having interconnecting voids, in which an upper surface of the ink-receiving layer has been subjected to plasma treatment, and the upper surface of the ink-receiving layer, prior to the plasma treatment, has a measured carbon elemental content of at least 40 percent. This kind of method, however, may be not applicable to functional solutions such as those including semiconductor and conductive solvents.

It is therefore desirable to have a method that is able to form a continuous film on a surface layer having a relatively low affinity with the film. It is also desirable to have a method that is able to form a continuous film including semiconductor, conductive or organic materials.

### BRIEF SUMMARY OF THE INVENTION

Examples of the present invention may provide a method of forming a continuous layer of film, the method comprising providing a substrate having a surface, forming a first patterned layer of film on the surface, the first patterned layer of film including a plurality of first film units separated from each other, and forming a second patterned layer of film over the first patterned layer of film, the second patterned layer of film extending along the first patterned layer of film and including a plurality of second film units separated from each other, each of the plurality of second film units connecting at least two immediately adjacent first film units of the first patterned layer of film.

Some examples of the present invention may also provide a method of forming a continuous layer of film, the method comprising providing a substrate having a surface, forming a first layer of film on the surface, the first layer of film including a plurality of film units separated from each other, and forming a second layer of film over the first layer of film, the second layer of film extending continuously along the plurality of film units of the first layer of film.

Examples of the present invention may further provide a method of forming a continuous layer of film, the method comprising providing a substrate having a surface, forming at least one first layer of film on the surface, the at least one first layer of film being separated from each other, each of the at least one first layer of film including a plurality of first film units, each of the first film units being separated from each other, and forming at least one second layer of film over the at least one first layer of film, each of the at least one second layer of film corresponding to one of the at least one first layer of film and extending along the first film units of the corresponding one of the at least one first layer of film.

Examples of the present invention may provide a device having a substrate on which a continuous layer of film is provided, the continuous of film including a first layer of film on a surface of the substrate, the first layer of film including a plurality of film units separated from each other, and a second layer of film over the first layer of film, the second layer of film extending continuously along the plurality of film units of the first layer of film.

Additional features and advantages of the present invention will be set forth in part in the description which follows, and in part will be obvious from the description, or may be learned by practice of the invention. The features and advantages of the invention will be realized and attained by means of the elements and combinations particularly pointed out in the appended claims.

It is to be understood that both the foregoing general description and the following detailed description are exemplary and explanatory only and are not restrictive of the invention, as claimed.

### BRIEF DESCRIPTION OF THE SEVERAL VIEWS OF THE DRAWINGS

The foregoing summary, as well as the following detailed description of the invention, will be better understood when read in conjunction with the appended drawings. For the purpose of illustrating the invention, there are shown in the drawings embodiments which are presently preferred. It should be understood, however, that the invention is not limited to the precise arrangements and instrumentalities shown.

In the drawings:

FIG. 1A is a schematic diagram illustrating a film insensitive to a substrate;

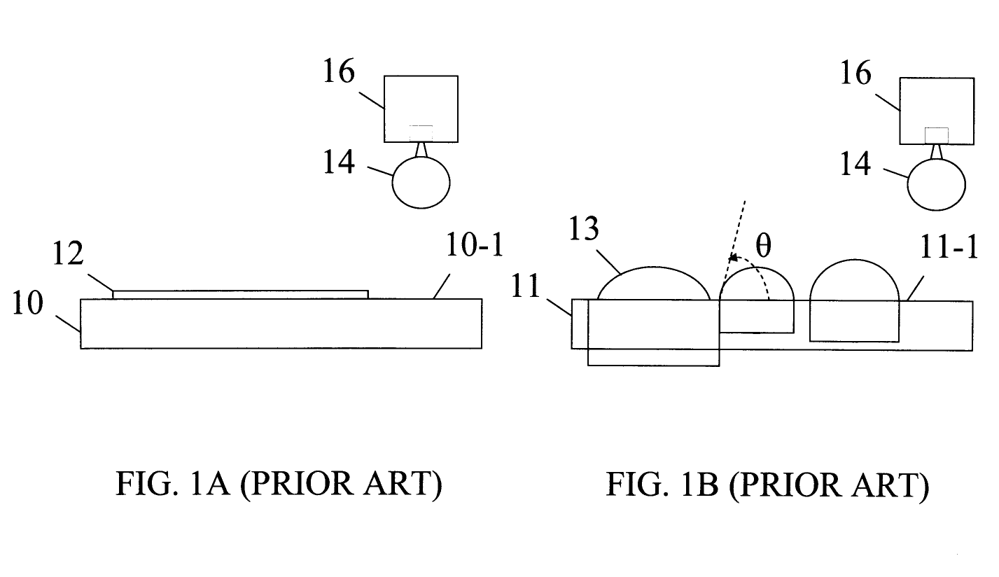

FIG. 1B is a schematic diagram illustrating a film sensitive to a substrate;

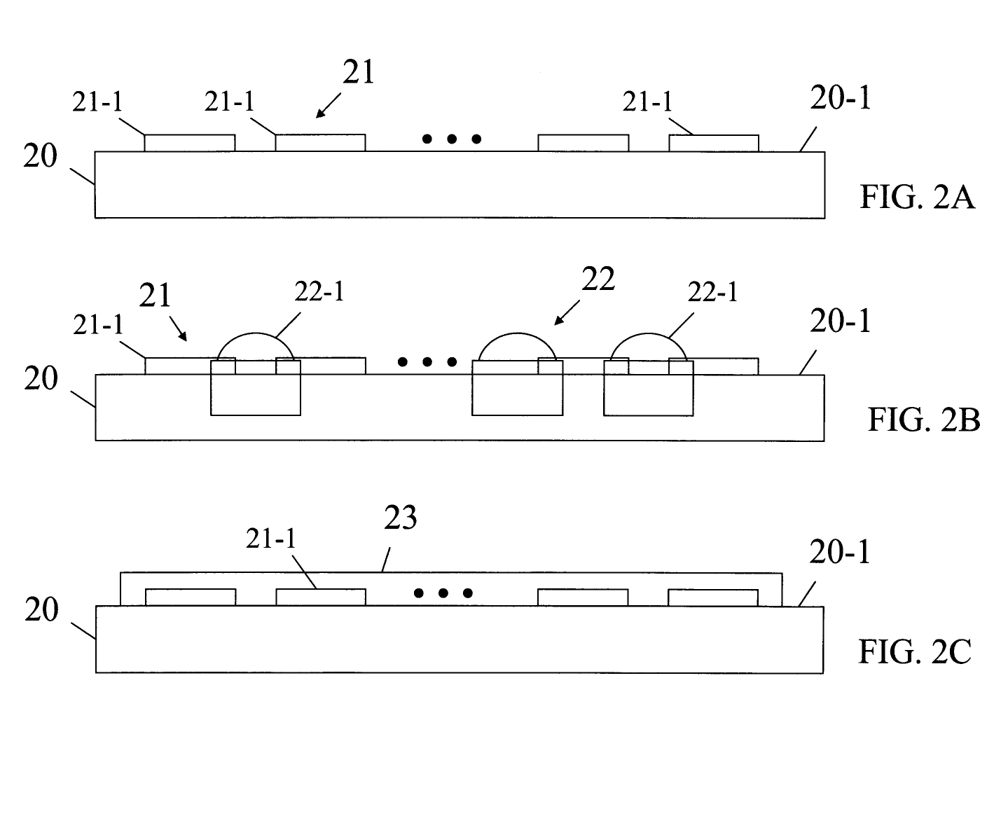

FIGS. 2A and 2B are schematic cross-sectional diagrams illustrating a method of forming a continuous film in accordance with an example of the present invention;

FIG. 2C is a schematic cross-sectional diagram illustrating a method of forming a continuous film in accordance with another example of the present invention;

FIGS. 2D and 2E are schematic top views illustrating methods of forming a continuous film in accordance with examples of the present invention;

FIGS. 3A and 3B are exemplary photos illustrating a comparison between a conventional method and a method consistent with an example of the present invention; and

FIGS. 4A and 4B are exemplary photos illustrating a comparison between a conventional method and a method consistent with an example of the present invention.

### DETAILED DESCRIPTION OF THE INVENTION

Reference will now be made in detail to the present embodiments of the invention, examples of which are illustrated in the accompanying drawings. Wherever possible, the same reference numbers will be used throughout the drawings to refer to the same or like parts.

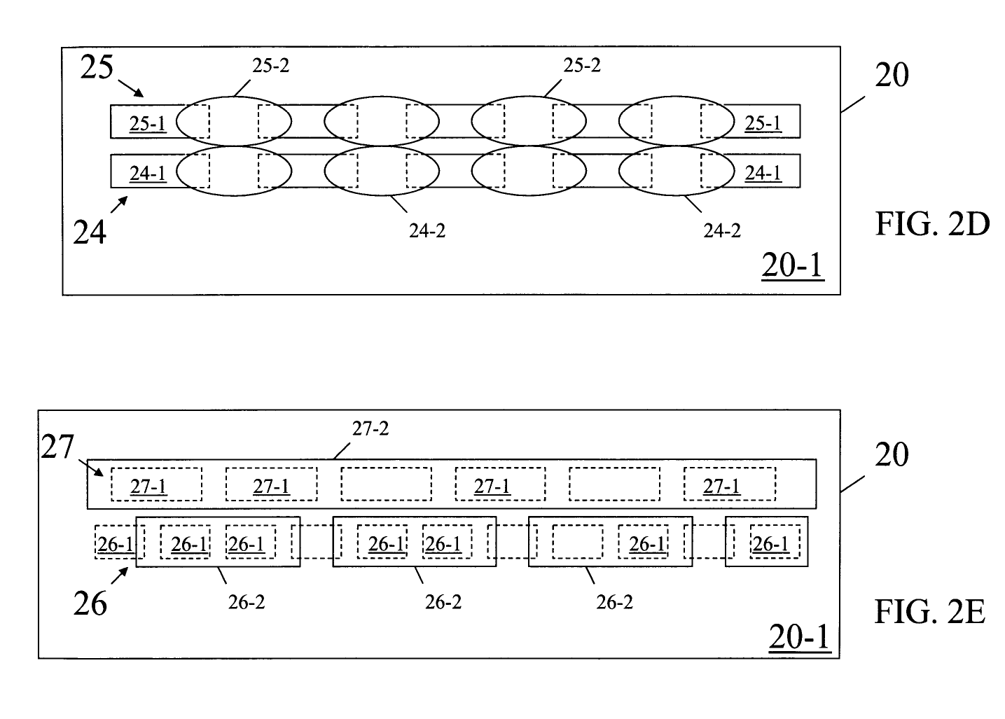

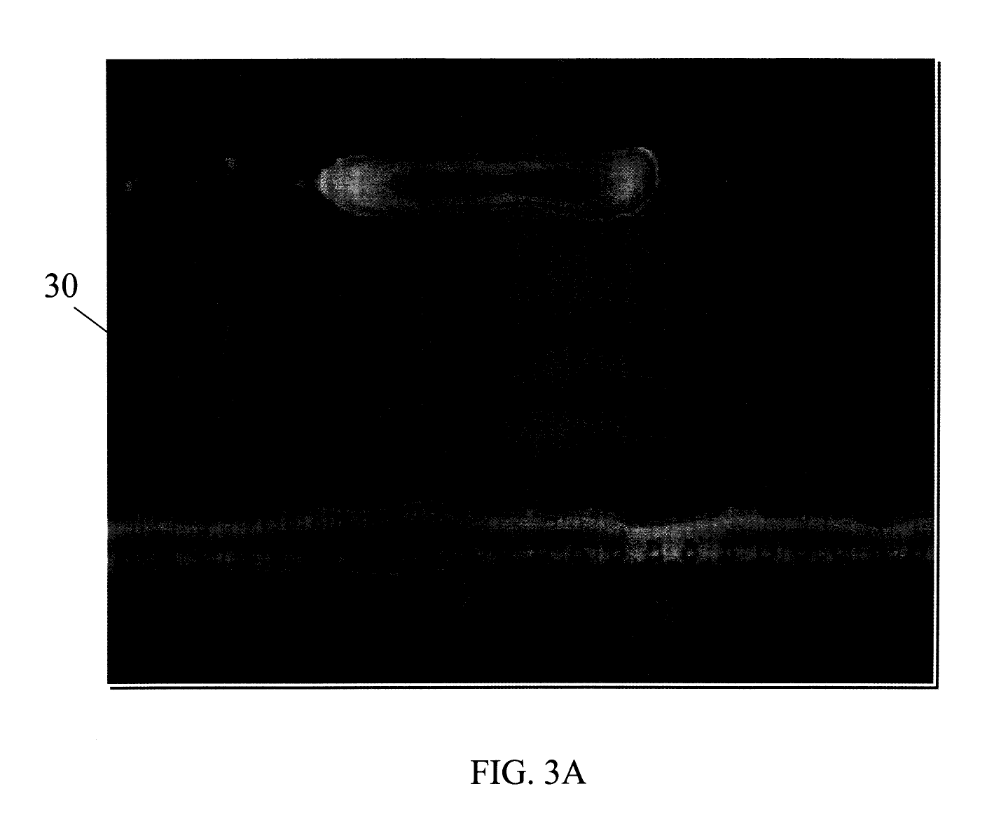

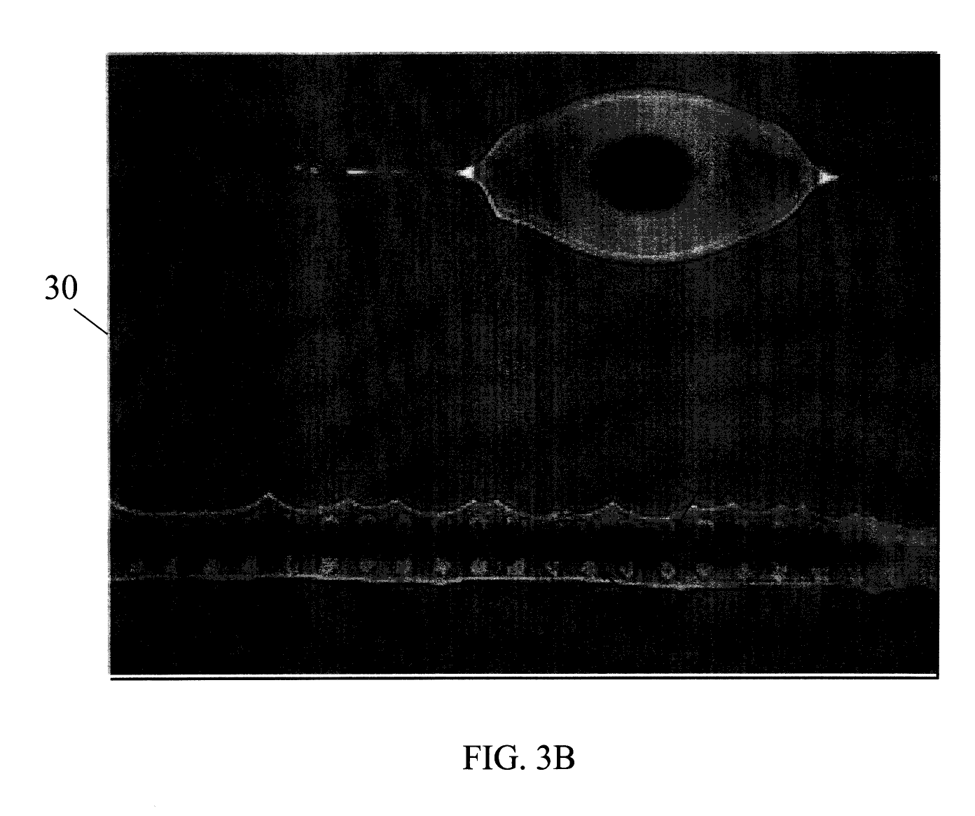

FIGS. 2A and 2B are schematic cross-sectional diagrams illustrating a method of forming a continuous film in accordance with an example of the present invention. Referring to FIG. 2A, a substrate 20 including a surface 20-1 is provided. The substrate 20 may include one of a glass substrate, a resin substrate and a silicon substrate. A first patterned layer of film 21 including a plurality of first film units 21-1 is formed on the surface 20-1. The first patterned layer of film 21 may initially be in a liquid state before subsequently becoming a dried film. The plurality of first film units 21-1 may be separated from each other. Each of the plurality of first film units 21-1 may be different in size. In one example according to the present invention, the first patterned layer of film 21 may include one or more conductive materials, such as silver (Ag), copper (Cu) and gold (Au) in a toluene solution. In another example, the first patterned layer of film 21 may include one or more semiconductor materials, such as poly (3-alkylthiophenes) (P3AT), poly (3-hexylthiophenes) (P3HT) and polyfluorene co-polymers like poly-9,9′-dioctylfluorene co-dithiophene (F8AT2). In still another example, the first patterned layer of film 21 may include one or more insulating materials, such as polyimide (PI), polyrinyl alcohol (PVA), polyrinyl phenol (PVP) and polymethyl methacrylate (PMMA). The process for forming the first patterned layer of film 21 may include but is not limited to inkjet printing, spin coating, screen printing, imprinting or deposition, which may be followed by a patterning and etching process.

Next, referring to FIG. 2B, a second patterned layer of film 22 including a plurality of second film units 22-1 is applied over the first patterned layer of film 21 on the surface 20-1. The second patterned layer of film 22 may initially be in a liquid state before eventually becoming a dried film. The plurality of second film units 22-1 may be separated from each other. Each of the second film units 22-1 may be arranged to connect two immediately adjacent first film units 21-1. Eventually, a continuous layer of film including the first patterned layer of film 21 and the second patterned layer of film 22 may be formed when the films 21 and 22 become dried. In other examples, each of the second film units 22-1 may be arranged to connect three or more immediately adjacent first film units 21-1. The first patterned layer of film 21 therefore may facilitate the spreading of the plurality of film units 22-1.

The second patterned layer of film 22 may include but is not limited to one of the conductive, semiconductor or insulating materials as previously discussed with respect to the first patterned layer of film 21. Furthermore, the second patterned layer of film 22 may be formed on the surface 20-1 by inkjet printing, spin coating, screen printing, imprinting, or deposition, which may be followed by a patterning and etching process or other suitable process. In one example, the second patterned layer of film 22 may include substantially the same material as the first patterned layer of film 21 and hence has substantially the same affinity with the surface 20-1 as the first patterned layer of film 21. In other examples, the second patterned layer of film 22 may have a relatively low affinity with the surface 20-1 and the first patterned layer of film 21 may have a relatively high affinity with the surface 20-1.

FIG. 2C is a schematic cross-sectional diagram illustrating a method of forming a continuous film in accordance with another example of the present invention. Referring to FIG. 2C, instead of applying a discontinuous film such as the second patterned layer of film 22 described and illustrated with reference to FIG. 2B, a continuous film 23 may be applied over the first patterned layer of film 21. In the absence of the first patterned layer of film 21, the continuous film 23 would become discontinuous if the continuous film 23 is sensitive to the surface 20-1 of the substrate 20.

FIGS. 2D and 2E are schematic top views illustrating methods of forming a continuous film in accordance with examples of the present invention. In these examples, two or more patterned layers of films may be formed on a surface of a substrate to facilitate the spreading of two or more films later applied over the substrate. Referring to FIG. 2D, a first patterned layer of film 24 including a plurality of first film units 24-1 being separated from each other may be formed on the surface 20-1 of the substrate 20. Furthermore, a second patterned layer of film 25 including a plurality of second film units 25-1 being separated from each other may be formed on the surface 20-1 of the substrate 20. Subsequently, a third patterned layer of film (not numbered) including a plurality of third film units 24-2 may be applied along the first patterned layer of film 24. Each of the third film units 24-2 may be arranged to connect two immediately adjacent first film units 24-1. Likewise, a fourth patterned layer of film (not numbered) including a plurality of fourth film units 25-2 may be applied along the second patterned layer of film 25. Each of the fourth film units 24-2 may be arranged to connect two immediately adjacent second film units 25-1. The first patterned layer of film 24 and the second patterned layer of film 25 may be separated from one another by a predetermined distance so that spreading of the third and fourth patterned layers of films thereon may result in a continuous film. That is, the continuous film thus formed may include the first, second, third and fourth patterned layers of films.

Referring to FIG. 2E, a first patterned layer of film 26 including a plurality of first film units 26-1 being separated from each other may be formed on the surface 20-1 of the substrate 20. Furthermore, a second patterned layer of film 27 including a plurality of second film units 27-1 being separated from each other may be formed on the surface 20-1 of the substrate 20. Subsequently, a third patterned layer of film (not numbered) including a plurality of third film units 26-2 may be applied along the first patterned layer of film 26. Each of the third film units 26-2 may be arranged to connect four immediately adjacent first film units 26-1 and bridge three gaps therebetween. A fourth layer of film (not numbered) 27-2 may be applied along the second patterned layer of film 27. The fourth layer of film is continuous along the length of the second patterned layer of film 27. The first patterned layer of film 26 and the second patterned layer of film 27 may be separated from one another by a predetermined distance so that spreading of the third and fourth patterned layers of films thereon may result in a continuous film.

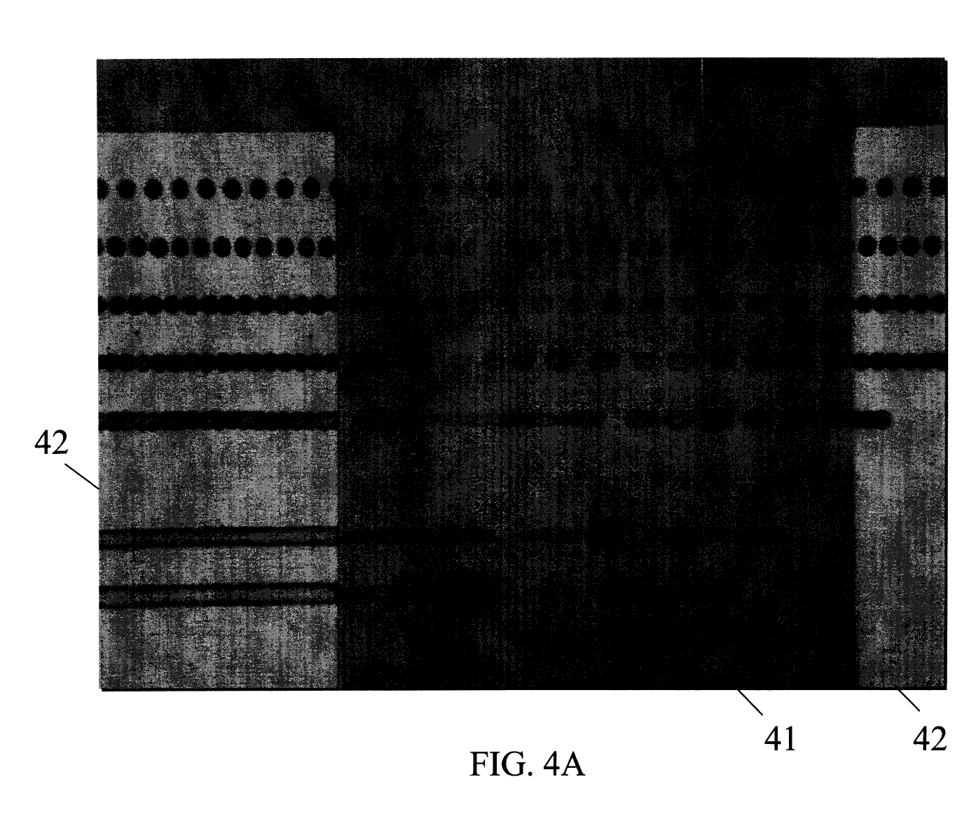

FIGS. 3A and 3B are exemplary photos illustrating a comparison between a conventional method and a method consistent with an example of the present invention. In an experimental design, a solution including 0.1 to 1.0 wt % (weight percentage) of P3HT in an anisole solvent is used to form a layer of film on a substrate including a surface 30 that has been treated by octadecyltrichlorosilane (OTS). The solution is provided from an inkjet printer including an inkjet orifice of 50 micrometer (um). The P3HT solution exhibits a relatively low affinity with the OTS-treated surface. Referring to FIG. 3A, in the upper portion, the conventional method applies droplets of the solution at a relatively high density but fails to form a continuous layer of film because the cohesion in the droplets is greater than the surface tension. As illustrated, a discontinuous layer of film 38 is formed, which may adversely affect the desired electrical characteristics. In the lower portion of FIG. 3A, the method according to an example of the present invention forms a patterned layer of film 31 including a plurality of film units 31-1 being separated from each other, and then applies a continuous film 32 over the patterned layer of film 31. The patterned layer of film 31 may help spread the continuous film 32 over the substrate surface 30 and prevent the continuous film 32 from eventually being disconnected.

Referring to FIG. 3B, the experimental conditions may be similar to those described and illustrated with reference to FIG. 3A except that two separate lines of film are formed for this illustrative example. In the upper portion of FIG. 3B, after applying two lines of droplets, the conventional method results in a discontinuous layer of film 39. By comparison, in the lower portion of FIG. 3B, a method according to an example of the present invention may form patterned layers of film 33 and 34 and then apply two lines of film respectively over the films 33 and 34, resulting in a continuous layer of film 35. Furthermore, the width “w₂” of the continuous layer of film 35 may be substantially two times the width “w₁” of the patterned layer of film 31 illustrated in FIG. 3A.

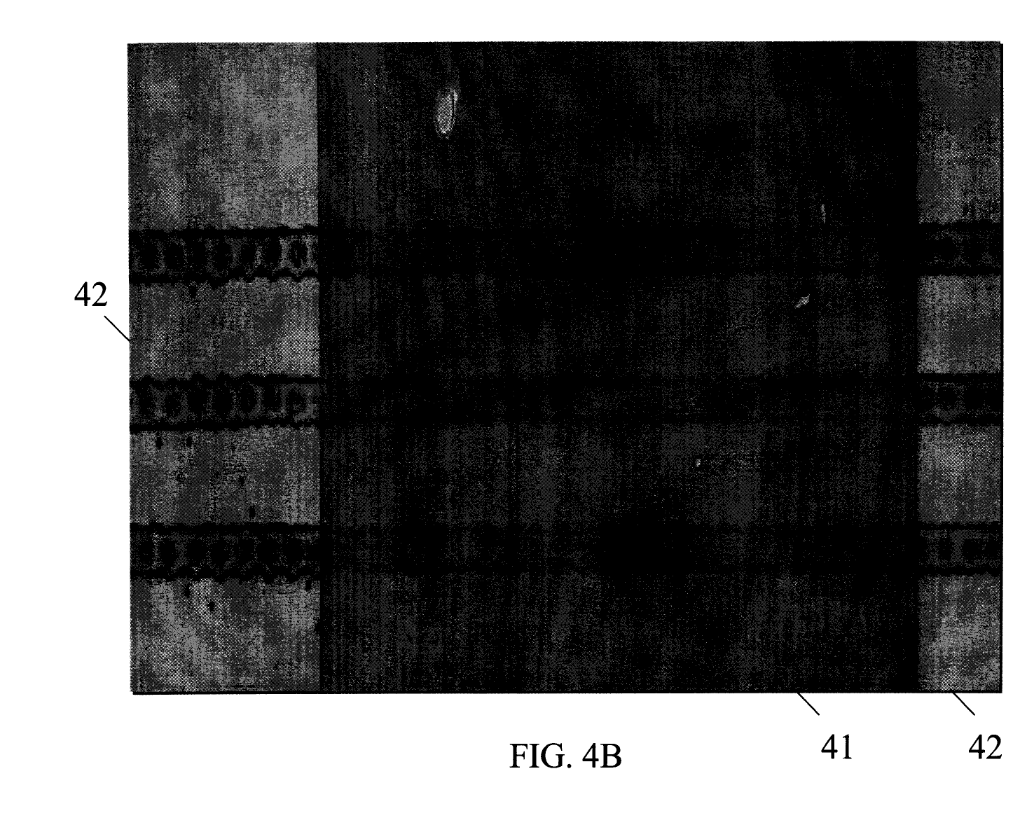

FIGS. 4A and 4B are exemplary photos illustrating a comparison between a conventional method and a method consistent with an example of the present invention. In one experiment, a solution including approximately 17 wt % of poly (3,4-ethylenedioxythiophene) (PEDOT) in water is used to form a layer of film on a surface 41 including silicon dioxide (SiO₂) and a surface 42 including indium tin oxide (ITO). The solution is provided from an inkjet printer including an inkjet orifice of about 50 um. Generally, the PEDOT solution exhibits a higher affinity with the ITO surface 42 than the SiO₂ surface 41. Referring to FIG. 4A, in the upper portion, the conventional method applies several lines of droplets of the solution at different droplet densities but fails to form any continuous layer of film on the SiO₂ surface 41 due to low affinity. By comparison, referring to FIG. 4B, a method according to an example of the present invention provides a layer of film 43, which is continuous on the ITO surface 41 and the SiO₂ surface 42.

The method consistent with an example of the present invention may be useful in various applications, including but not limited to the fabrication of passive components (such as resistors, inductors and capacitors), active components (such as thin film transistors and memory devices), and electronic products (such as displays, sensors and solar cells). Therefore, the present invention may also provide an electrical component or device that includes a first patterned layer of film further including a plurality of film units and a second layer of film continuously extending over the first patterned layer of film.

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

Further, in describing representative embodiments of the present invention, the specification may have presented the method and/or process of the present invention as a particular sequence of steps. However, to the extent that the method or process does not rely on the particular order of steps set forth herein, the method or process should not be limited to the particular sequence of steps described. As one of ordinary skill in the art would appreciate, other sequences of steps may be possible. Therefore, the particular order of the steps set forth in the specification should not be construed as limitations on the claims. In addition, the claims directed to the method and/or process of the present invention should not be limited to the performance of their steps in the order written, and one skilled in the art can readily appreciate that the sequences may be varied and still remain within the spirit and scope of the present invention.

I/We claim:

1. A method of forming a continuous layer of film, the method comprising:
providing a substrate having a surface;
forming a first patterned layer of film on the surface, the first patterned layer of film including a plurality of first film units separated from each other; and
forming a second patterned layer of film over the first patterned layer of film, the second patterned layer of film extending along the first patterned layer of film and including a plurality of second film units separated from each other, each of the plurality of second film units connecting at least two immediately adjacent first film units of the first patterned layer of film.

2. The method of claim 1, wherein the substrate includes one of a glass substrate, a resin substrate and a silicon substrate.

3. The method of claim 1, wherein the first patterned layer of film includes one of a conductive material, a semiconductor material and an insulating material.

4. The method of claim 3, wherein the conductive material includes at least one of silver, copper or gold.

5. The method of claim 3, wherein the semiconductor material includes at least one of poly (3-alkylthiophenes) (P3AT), poly (3-hexylthiophenes) (P3HT) or poly-9,9′-dioctylfluorene co-dithiophene (F8T2).

6. The method of claim 3, wherein the insulating material includes at least one of polyimide (PI), polyrinyl alcohol (PVA), polyrinyl phenol (PVP) or polymethyl methacrylate (PMMA).

7. The method of claim 1, wherein the second patterned layer of film includes one of a conductive material, a semiconductor material and an insulating material.

8. The method of claim 7, wherein the conductive material includes at least one of silver, copper or gold.

9. The method of claim 7, wherein the semiconductor material includes at least one of poly (3-alkylthiophenes) (P3AT), poly (3-hexylthiophenes) (P3HT) or poly-9,9′-dioctylfluorene co-dithiophene (F8T2).

10. The method of claim 7, wherein the insulating material includes at least one of polyimide (PI), polyrinyl alcohol (PVA), polyrinyl phenol (PVP) or polymethyl methacrylate (PMMA).

11. A method of forming a continuous layer of film, the method comprising:
providing a substrate having a surface;
forming a first layer of film on the surface, the first layer of film including a plurality of film units separated from each other; and
forming a second layer of film over the first layer of film, the second layer of film extending continuously along the plurality of film units of the first layer of film.

12. The method of claim 11, wherein at least one of the first layer of film or the second layer of film includes one of a conductive material, a semiconductor material and an insulating material.

13. The method of claim 12, wherein the conductive material includes at least one of silver, copper or gold.

14. The method of claim 12, wherein the semiconductor material includes at least one of poly (3-alkylthiophenes) (P3AT), poly (3-hexylthiophenes) (P3HT) or poly-9,9′-dioctylfluorene co-dithiophene (F8T2).

15. The method of claim 12, wherein the insulating material includes at least one of polyimide (PI), polyrinyl alcohol (PVA), polyrinyl phenol (PVP) or polymethyl methacrylate (PMMA).

16. A method of forming a continuous layer of film, the method comprising:
providing a substrate having a surface;
forming at least one first layer of film on the surface, the at least one first layer of film being separated from each other, each of the at least one first layer of film including a plurality of first film units, each of the first film units being separated from each other; and
forming at least one second layer of film over the at least one first layer of film, each of the at least one second layer of film corresponding to one of the at least one first layer of film and extending along the first film units of the corresponding one of the at least one first layer of film.

17. The method of claim 16, wherein one of the at least one second layer of film includes a plurality of second film units being separated from each other.

18. The method of claim 17, wherein each of the plurality of second film units connects at least two immediately adjacent first film units of a corresponding one of the at least one first layer of film.

19. The method of claim 16, wherein one of the at least one second layer of film extends continuously along the plurality of first film units of a corresponding one of the at least one first layer of film.

20. The method of claim 16, wherein one of the at least one first layer of film and the at least one second layer of film includes one of a conductive material, a semiconductor material and an insulating material.

21. The method of claim 20, wherein the conductive material includes at least one of silver, copper or gold.

22. The method of claim 20, wherein the semiconductor material includes at least one of poly (3-alkylthiophenes) (P3AT), poly (3-hexylthiophenes) (P3HT) or poly-9,9′-dioctylfluorene co-dithiophene (F8T2).

23. The method of claim 20, wherein the insulating material includes at least one of polyimide (PI), polyrinyl alcohol (PVA), polyrinyl phenol (PVP) or polymethyl methacrylate (PMMA).

24. The method of claim 16, wherein forming one of the first patterned layer of film and the second layer of film includes one of an inkjet printing, spin coating, screen printing, imprinting and deposition process.
